(19) United States
(12) Patent Application Publication
(10) Pub. No.: US 2026/0293562 A1
(43) Pub. Date: Sep. 24, 2026

(54) WORKPIECE PROCESSING METHOD AND SEMICONDUCTOR DEVICE MANUFACTURING METHOD

(71) Applicant: DISCO CORPORATION, Tokyo (JP)

(72) Inventors: Kosei Kiyohara, Tokyo (JP); Yukitoshi Hayashi, Tokyo (JP); Shoichi Hasegawa, Tokyo (JP)

(21) Appl. No.: 19/337,418

(22) Filed: Sep. 23, 2025

(30) Foreign Application Priority Data
Mar. 19, 2025 (JP) 2025-045849

(51) Int. Cl. H01L 21/78; B24B 7/22; B24B 51/00; H01L 21/304

(52) U.S. Cl. CPC H10P 54/00; B24B 7/228; B24B 51/00; H10P 52/00

(57) ABSTRACT

Provided is a workpiece processing method that allows a standard processing recipe to be easily customized. The workpiece processing method includes creating a special recipe by customizing a standard recipe in a processing apparatus in which the standard recipe is stored, and processing the workpiece according to the special recipe using the processing apparatus.

### BACKGROUND

### 1. Technical Field

The present disclosure relates to a workpiece processing method and a semiconductor device manufacturing method.

### 2. Description of the Related Art

A semiconductor wafer having a plurality of semiconductor devices, such as ICs or LSIs, formed in a top surface thereof and defined by division lines has a back surface thereof ground with a grinding apparatus and is formed to an intended thickness to be subsequently divided into individual semiconductor devices with a dicing apparatus. The separated individual semiconductor devices are used for electronic devices such as smartphones or personal computers.

The grinding apparatus includes a chuck table for holding the semiconductor wafer, a grinding unit on which a grinding wheel for grinding the semiconductor wafer held on the chuck table is rotatably mounted, a processing feed unit for bringing the grinding unit closer to and away from the semiconductor wafer, and a thickness measurement unit for measuring a thickness of the semiconductor wafer, and can finish the semiconductor wafer to an intended thickness with high precision (see, e.g., JP 2022-067769 A).

The semiconductor wafer to be ground with the grinding apparatus includes various types such as a silicon wafer, a sapphire wafer, a gallium nitride wafer, and a silicon carbide wafer. In addition, since a required quality such as a finishing thickness or thickness precision varies, a processing recipe (processing conditions) for grinding the semiconductor wafer is created according to the type of the semiconductor wafer, the finishing thickness, and the required quality.

### SUMMARY

However, when a workpiece, the required quality, or the like changes, it is necessary to accordingly change the processing recipe, but a problem arises in that creating an appropriate processing recipe according to the workpiece, the required quality, or the like is troublesome and time-consuming.

A task of the present disclosure is to provide a workpiece processing method that allows a user to easily create a processing recipe and a semiconductor device manufacturing method.

According to the present disclosure, the following workpiece processing method that solves the problem described above is provided. In other words, there is provided “A workpiece processing method” including: creating a special recipe by customizing a standard recipe in a processing apparatus in which the standard recipe is stored; and processing the workpiece according to the special recipe using the processing apparatus.

According to the present disclosure, the following semiconductor device manufacturing method that solves the problem described above is provided. In other words, there is provided “A semiconductor device manufacturing method” including: preparing a semiconductor wafer having a semiconductor device in each of surface regions thereof defined by a plurality of division lines crossing each other; creating a special recipe by customizing a standard recipe in a processing apparatus in which the standard recipe is stored; grinding and thinning a back surface of the semiconductor wafer according to the special recipe using the processing apparatus; and dividing the semiconductor wafer along the division lines to form a plurality of the semiconductor devices.

According to the present disclosure, the following semiconductor device manufacturing method that solves the problem described above is provided. In other words, there is provided “A semiconductor device manufacturing method” including: preparing a semiconductor wafer having a semiconductor device in each of surface regions thereof defined by a plurality of division lines crossing each other; creating a special recipe by customizing a standard recipe in a processing apparatus in which the standard recipe is stored; and dividing the semiconductor wafer along the division lines to form a plurality of the semiconductor devices, the dividing including dicing the semiconductor wafer using the processing apparatus along the division lines of the semiconductor wafer according to the special recipe.

Preferably, in the creating the special recipe, a controller of the processing apparatus determines whether or not the customization can be allowed on the basis of a correlation between a plurality of items of the standard recipe and, when determining that the customization can be allowed, the controller stores details of the customization as the special recipe and, when determining that the customization cannot be allowed, the controller limits the customization.

It is desirable that, in the creating the special recipe, when determining that the customization cannot be allowed, the controller displays, on a display of the processing apparatus, an allowable one and an unallowable one of details of the customization.

It may also be possible that, in the creating the special recipe, when determining that the customization cannot be allowed, the controller displays, on a display of the processing apparatus, a limit value to an unallowable one of details of the customization.

According to the present disclosure, a user can easily create a processing recipe.

### BRIEF DESCRIPTION OF THE DRAWINGS

FIG. 1 is a perspective view of a semiconductor wafer;

FIG. 2 is a schematic diagram of a grinding apparatus;

FIG. 3 is a schematic diagram of a blade dicing apparatus;

FIG. 4 is a schematic diagram of a laser dicing apparatus; and

FIG. 5A is a schematic diagram illustrating a state where the semiconductor wafer illustrated in FIG. 1 is bonded to a dicing tape and FIG. 5B is a schematic diagram illustrating a state where a protection member is peeled from the semiconductor wafer illustrated in FIG. 5A.

### DETAILED DESCRIPTION

Referring to the drawings, a description will be given below of embodiments of the present disclosure.

### Preparing a Semiconductor Wafer

In the present embodiment, first, a semiconductor wafer is prepared that has respective semiconductor devices in individual surface regions thereof defined by a plurality of division lines crossing each other.

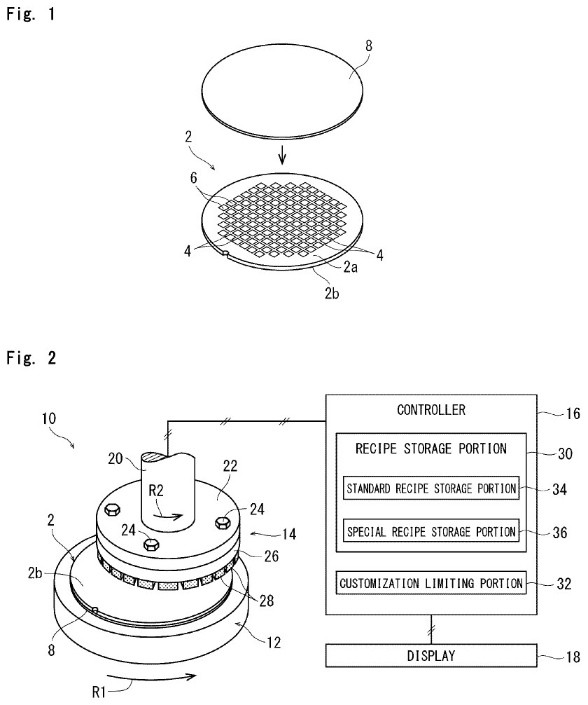

The semiconductor wafer to be prepared may appropriately be, e.g., a disc-shaped semiconductor wafer 2 illustrated in FIG. 1. The semiconductor wafer 2 may be formed of a semiconductor material such as silicon (Si), sapphire (Al₂O₃), gallium nitride (GaN), or silicon carbide (SiC). A top surface 2a of a semiconductor wafer 2 is partitioned into a plurality of regions by a plurality of division lines 4 crossing each other and, in the respective regions resulting from the partitioning, semiconductor devices 6, such as ICs (Integrated Circuits), are formed. The semiconductor wafer 2 illustrated in FIG. 1 is partitioned into a plurality of rectangular regions by the division lines 4 in a grid pattern, but the division lines 4 are not limited to the grid pattern, and the semiconductor wafer 2 may also be partitioned into, e.g., hexagonal regions by the division lines 4.

In the present embodiment, a circular protection member 8 for protecting the semiconductor devices 6 is bonded to the top surface 2a of the semiconductor wafer 2. A diameter of the protection member 8 may be the same as a diameter of the semiconductor wafer 2, or may also be slightly larger than the diameter of the semiconductor wafer 2. The protection member 8 may appropriately be an adhesive tape or a thermo-compression tape. The thermo-compression tape is a tape made of a thermoplastic synthetic resin (e.g., polyolefinic resin) having no adhesive compound, which is a tape that is softened or melted to exhibit an adhesive force when heated to a temperature in the vicinity of a melting point.

### Creating a Special Recipe

After preparing the semiconductor wafer 2, in a processing apparatus in which a standard recipe is stored, a special recipe is created by customizing the standard recipe.

### Grinding Apparatus 10

The creating a special recipe can be performed in, e.g., a grinding apparatus 10 illustrated in FIG. 2. The grinding apparatus 10 includes a chuck table 12 for holding a workpiece, a grinding unit 14 for grinding the workpiece held on the chuck table 12, a controller 16 for controlling actuation of the grinding apparatus 10, a display 18 for displaying the standard recipe or the like, and an input interface (not shown) for inputting a work instruction, information, or the like to the controller 16.

### Chuck Table 12 of Grinding Apparatus 10

On an upper end of the chuck table 12, a disc-shaped porous member (not shown) is placed. The porous member is formed of a porous ceramic or the like and connected to a suction pump (not shown). The chuck table 12 generates a suction force on an upper surface of the porous member by using the suction pump to suction-hold the workpiece placed on an upper surface of the chuck table 12.

### Grinding Unit 14 of Grinding Apparatus 10

The grinding unit 14 includes a vertically extending spindle 20, a disc-shaped wheel mount 22 fixed to a lower end of the spindle 20, and an annular grinding wheel 26 fastened to a lower surface of the wheel mount 22 by using bolts 24. To a circumferential edge portion of a lower surface of the grinding wheel 26, a plurality of grinding stones 28 are fixed to be arranged in an annular configuration and spaced apart from each other in a circumferential direction.

### Controller 16 of Grinding Apparatus 10

The controller 16 may be configured to include a computer having a processor and a memory. As illustrated in FIG. 2, the controller 16 includes a recipe storage portion 30 and a customization limiting portion 32.

### Recipe Storage Portion 30 of Controller 16

The recipe storage portion 30 stores a processing recipe according to a type of the workpiece, a required quality, processing details, and the like. The recipe storage portion 30 has a standard recipe storage portion 34 for storing a standard recipe and a special recipe storage portion 36 for storing the special recipe created by customizing details of the standard recipe.

### Standard Recipe Storage Portion 34 of Recipe Storage Portion 30

The standard recipe stored in the standard recipe storage portion 34 is a processing recipe set in advance for each user at a maker of the grinding apparatus 10 according to the type of the workpiece, the required quality, the processing details, and the like. For example, as the standard recipe when a silicon wafer is to be processed, the following processing recipe may be stored in advance in the standard recipe storage portion 34.

### Standard Recipe

Rotation Number of Spindle: 6000 rpm
Rotation Number of Chuck Table: 300 rpm
Processing Feed Speed: 0.5 μm/s

### Special Recipe Storage Portion 36 of Recipe Storage Portion 30

The special recipe to be stored in the special recipe storage portion 36 is a processing recipe obtained by customizing the details of the standard recipe by the user of the grinding apparatus 10. For each of processing conditions of the special recipe, an arbitrary numerical value can be selected from a predetermined numerical value range. For example, in the special recipe for the silicon wafer, for a rotation number of the spindle 20, a rotation number of the chuck table 12, and a processing feed speed of the spindle 20, arbitrary numerical values can be selected from the following numerical value ranges. However, the customization is limited so as to prevent a safety factor from being excessively lowered and allow appropriate processing to be performed.

### Selectable Numerical Value Ranges

Rotation Number of Spindle: 1000 rpm to 20000 rpm
Rotation Number of Chuck Table: 10 rpm to 2000 rpm
Processing Feed Speed: 0.1 μm/s to 1.0 μm/s

### Customization Limiting Portion 32 of Controller 16

A customization limiting portion 32 displays, on the display 18, the standard recipe stored in the standard recipe storage portion 34 and determines, when customizing the details of the standard recipe, whether or not the customization can be allowed on the basis of correlations between a plurality of items of the standard recipe. In addition, when determining that the customization can be allowed, the customization limiting portion 32 stores details of the customization as the special recipe in the special recipe storage portion 36 while, when determining that the customization cannot be allowed, the customization limiting portion 32 limits the customization. The customization limiting portion 32 can limit the customization on the basis of correlations between the rotation number of the spindle 20, the rotation number of the chuck table 12, and the processing feed speed of the spindle 20.

By way of example, it is assumed that the user has attempted the following customization of the foregoing standard recipe for the silicon wafer in which the safety factor is excessively lowered.

### Details of Customization by User

Rotation Number of Spindle: Changed from 6000 rpm to 8000 rpm
Rotation Number of Chuck Table: Changed from 300 rpm to 400 rpm
Processing Feed Speed: Changed from 0.5 μm/s to 1.0 μm/s

As a result, the safety factor is excessively lowered, and therefore the customization limiting portion 32 determines that the customization cannot be allowed, and limits the customization. Then, the customization limiting portion 32 displays, on the display 18, the allowable one and the unallowable one of the details of the customization input by the user. Alternatively, the customization limiting portion 32 can also display, on the display 18, a limit value to the unallowable one of the details of the customization input by the user.

For example, as shown below in First Customization Limit, the customization limiting portion 32 allows numerical values input by the user for the rotation number of the spindle 20 and the rotation number of the chuck table 12, while displaying, on the display 18, not only refusal of the numerical value input by the user for the processing feed speed, but also a limit value to the processing feed speed.

### First Customization Limit

Rotation Number of Spindle: 8000 rpm Allowable
Rotation Number of Chuck Table: 400 rpm Allowable
Processing Feed Speed: 1.0 μm/s Unallowable
*Set processing feed speed to 0.8 μm/s or less.

Alternatively, as shown below in Second Customization Limit, the customization limiting portion 32 not only allows the numerical value input by the user for the processing feed speed and refuses the numerical values input by the user for the rotation number of the spindle 20 and the rotation number of the chuck table 12, but also can display, on the display 18, a limit value to the rotation number of the spindle 20 and a limit value to the rotation number of the chuck table 12. Note that both of First and Second Customization Limits may also be displayed on the display 18.

### Second Customization Limit

Rotation Number of Spindle: 8000 rpm Unallowable
Rotation Number of Chuck Table: 400 rpm Unallowable
Processing Feed Speed: 1.0 μm/s Allowable
*Set rotation number of spindle to 11000 rpm or more.
Set rotation number of chuck table to 550 rpm or more.

By way of another example, it is assumed that the user has attempted the following customization of the foregoing standard recipe for the silicon wafer in which the safety factor is excessively lowered.

### Details of Customization by User

Rotation Number of Spindle: Left invariably at 6000 rpm
Rotation Number of Chuck Table: Changed from 300 rpm to 400 rpm
Processing Feed Speed: Changed from 0.5 μm/s to 1.0 μm/s

Thus, the safety factor is excessively lowered, and therefore it may be possible for the customization limiting portion 32 to determine that the customization cannot be allowed and limit the customization, while displaying, on the display 18, at least one of Third and Fourth Customization Limits shown below.

### Third Customization Limit

Rotation Number of Spindle: 6000 rpm Allowable
Rotation Number of Chuck Table: 400 rpm Allowable
Processing Feed Speed: 1.0 μm/s Unallowable
*Set processing feed speed to 0.65 μm/s or less.

### Fourth Customization Limit

Rotation Number of Spindle: 6000 rpm Unallowable
Rotation Number of Chuck Table: 400 rpm Unallowable
Processing Feed Speed: 1.0 μm/s Allowable
*Set rotation number of spindle to 11000 rpm or more.
Set rotation number of chuck table to 550 rpm or more.

Thus, the customization limiting portion 32 displays, on the display 18, the standard recipe stored in the standard recipe storage portion 34, determines whether or not the customization can be allowed on the basis of the correlations between the plurality of items of the standard recipe when customizing the details of the standard recipe, and limits the customization when determining that the customization cannot be allowed. Consequently, it is possible to prevent the safety factor from being excessively lowered when the user customizes the processing recipe, and it may also be possible to perform appropriate processing. Note that, as the customization limit, different limits may be set according to the type of the workpiece, the required quality, the processing details, or the like.

### Display 18 of Grinding Apparatus 10

The display 18 displays the processing recipe stored in the recipe storage portion 30 on the basis of an instruction from the controller 16. As described above, the standard recipe stored in the standard recipe storage portion 34 and the special recipe stored in the special recipe storage portion 36 may be displayed on the display 18. In addition, a limit when the standard recipe is to be customized is also displayed on the display 18. The display 18 may be a touch panel functioning also as an input interface.

### Blade Dicing Apparatus 38

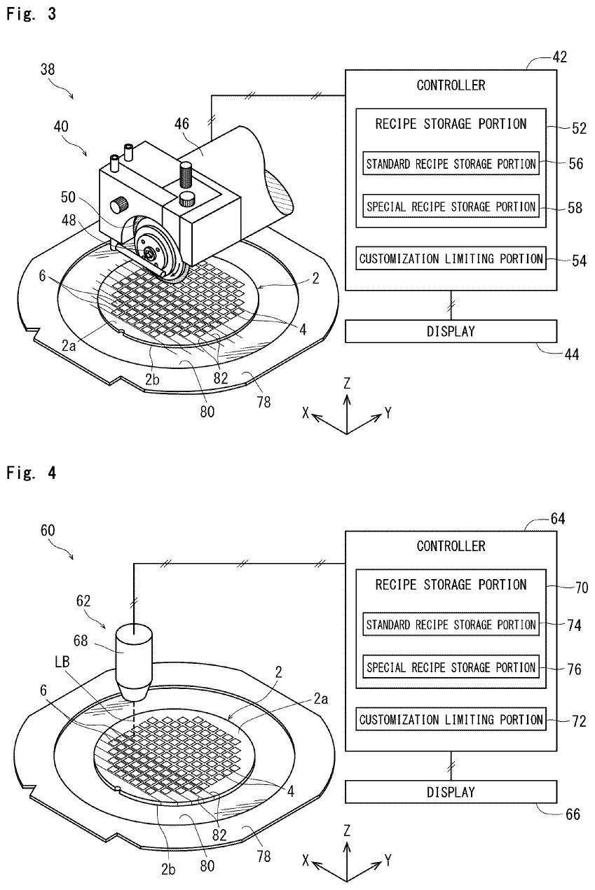

The creating a special recipe can also be performed in a blade dicing apparatus 38 illustrated in FIG. 3. The blade dicing apparatus 38 includes a chuck table (not shown) for holding the workpiece, a cutting unit 40 for cutting the workpiece held on the chuck table, a controller 42 for controlling actuation of the blade dicing apparatus 38, a display 44 for displaying the standard recipe or the like, and an input interface (not shown) for inputting a work instruction, information, or the like to the controller 16. The chuck table of the blade dicing apparatus 38 may appropriately have the same configuration as that of the chuck table 12 of the grinding apparatus 10, and therefore a description thereof is omitted.

### Cutting Unit 40 of Blade Dicing Apparatus 38

The cutting unit 40 includes a spindle housing 46 movable in each of a Y-axis direction and a Z-axis direction, a spindle 48 supported by the spindle housing 46 to be rotatable around an axial line extending in the Y-axis direction, and an annular cutting blade 50 fixed to a leading end of the spindle 48. A cutting edge around an outer circumference of the cutting blade 50 may be made appropriately of abrasive grains made of diamond, CBN (Cubic Boron Nitride), or the like bonded together with a bond material such as vitrified bond.

### Controller 42 of Blade Dicing Apparatus 38

The controller 42 may be configured to include a computer having a processor and a memory. As illustrated in FIG. 3, the controller 42 includes a recipe storage portion 52 and a customization limiting portion 54.

### Recipe Storage Portion 52 of Controller 42

The recipe storage portion 52 stores a processing recipe according to the type of the workpiece, the required quality, the processing details, or the like. The recipe storage portion 52 has a standard recipe storage portion 56 for storing the standard recipe and a special recipe storage portion 58 for storing the special recipe created by customizing the details of the standard recipe.

### Standard Recipe Storage Portion 56 of Recipe Storage Portion 52

The standard recipe stored in the standard recipe storage portion 56 is a processing recipe set in advance for each user at a maker of the blade dicing apparatus 38 according to the type of the workpiece, the required quality, the processing details, or the like. For example, as the standard recipe when a sapphire wafer is to be processed, the following processing recipe may be stored in advance in the standard recipe storage portion 56.

### Standard Recipe

Rotation Number of Spindle: 15000 rpm
Processing Feed Speed: 10 mm/s

### Special Recipe Storage Portion 58 of Recipe Storage Portion 52

The special recipe stored in the special recipe storage portion 58 is a processing recipe resulting from customization of the details of the standard recipe by a user of the blade dicing apparatus 38. For each of the processing conditions of the special recipe, an arbitrary numerical value can be selected from a predetermined numerical value range. For example, in the special recipe for the sapphire wafer, for the rotation number of the spindle 48 and the processing feed speed of the chuck table, arbitrary numerical values can be selected from the following numerical value ranges. However, the customization is limited so as to prevent the safety factor from being excessively lowered and allow appropriate processing to be performed.

### Selectable Numerical Value Ranges

Rotation Number of Spindle: 10000 rpm to 40000 rpm
Processing Feed Speed: 5 mm/s to 100 mm/s

### Customization Limiting Portion 54 of Controller 42

A customization limiting portion 54 displays, on the display 44, the standard recipe stored in the standard recipe storage portion 56 and determines, when customizing the details of the standard recipe, whether or not the customization can be allowed on the basis of the correlations between the plurality of items of the standard recipe. When determining that the customization can be allowed, the customization limiting portion 54 stores the details of the customization as the special recipe in the special recipe storage portion 58 while, when determining that the customization cannot be allowed, the customization limiting portion 54 limits the customization. The customization limiting portion 54 can limit the customization on the basis of the correlation between the rotation number of the spindle 48 and the processing feed speed of the chuck table.

For example, it is assumed that, with regard to the foregoing standard recipe for the sapphire wafer, the user has attempted the following customization in which the safety factor is excessively lowered.

### Details of Customization by User

Rotation Number of Spindle: Changed from 15000 rpm to 30000 rpm
Processing Feed Speed: Changed from 10 mm/s to 20 mm/s

Consequently, the safety factor is excessively lowered, and therefore the customization limiting portion 54 determines that the customization cannot be allowed, and limits the customization. Then, the customization limiting portion 54 displays, on the display 44, the allowable one and the unallowable one of the details of the customization input by the user. The customization limiting portion 54 can also display, on the display 44, a limit value to the unallowable one of the details of the customization input by the user.

For example, as in Customization Limit shown below, for the processing feed of the chuck table, the customization limiting portion 54 allows a numerical value input by the user while, for the rotation number of the spindle 48, the customization limiting portion 54 displays, on the display 44, refusal of the numerical value input by the user as well as the limit value to the rotation number of the spindle 48.

### Customization Limit

Rotation Number of Spindle: 30000 rpm Unallowable
Processing Feed Speed: 20 mm/s Allowable
*Set rotation number of spindle to 20000 rpm or less.

Thus, the customization limiting portion 54 displays, on the display 44, the standard recipe stored in the standard recipe storage portion 56, determines whether or not customization can be allowed on the basis of the correlations between the plurality of items of the standard recipe when customizing the details of the standard recipe, and limits the customization when determining that the customization cannot be allowed. Therefore, when the user customizes the processing recipe, it is possible to prevent the safety factor from being excessively lowered and allow appropriate processing to be performed. Note that, as the customization limit, different limits may be set according to the type of the workpiece or the like.

### Display 44 of Blade Dicing Apparatus 38

The display 44 displays the processing recipe stored in the recipe storage portion 52 on the basis of an instruction from the controller 42. As described above, the standard recipe stored in the standard recipe storage portion 56 or the special recipe stored in the special recipe storage portion 58 may be displayed on the display 44. In addition, a limit when the standard recipe is to be customized is also displayed on the display 44. The display 44 may also be a touch panel functioning also as an input interface.

### Laser Dicing Apparatus 60

The creating a special recipe can also be performed in a laser dicing apparatus 60 illustrated in FIG. 4. The laser dicing apparatus 60 includes a chuck table (not shown) for holding the workpiece, a laser beam application unit 62 for applying a laser beam LB to the workpiece held on the chuck table, a controller 64 for controlling actuation of the laser dicing apparatus 60, a display 66 for displaying the standard recipe or the like, and an input interface (not shown) for inputting a work instruction, information, or the like to the controller 16. The chuck table of the laser dicing apparatus 60 may appropriately have the same configuration as that of the chuck table 12 of the grinding apparatus 10, and therefore a description thereof is omitted.

### Laser Beam Application Unit 62 of Laser Dicing Apparatus 60

A laser beam application unit 62 includes an oscillator (not shown) for oscillating the laser beam LB and a concentrator 68 for concentrating the pulse laser beam LB oscillated from the oscillator. A wavelength of the laser beam LB oscillated from the oscillator is set appropriately according to the type of the workpiece, the required quality, the processing details, or the like. For example, when ablation processing is to be performed, the laser beam LB is set at a wavelength (which may appropriately be 355 nm in a case of the silicon wafer) absorbable by the workpiece and, when a modifying layer is to be formed inside of the workpiece, the laser beam LB may be set at a wavelength (which may appropriately be 1064 nm in the case of the silicon wafer) transparent to the workpiece.

### Controller 64 of Laser Dicing Apparatus 60

The controller 64 may be configured to include a computer having a processor and a memory. As illustrated in FIG. 4, the controller 64 includes a recipe storage portion 70 and a customization limiting portion 72.

### Recipe Storage Portion 70 of Controller 64

The recipe storage portion 70 stores a processing recipe according to the type of the workpiece, the required quality, the processing details, or the like. The recipe storage portion 70 has a standard recipe storage portion 74 for storing the standard recipe and a special recipe storage portion 76 for storing the special recipe created by customizing the details of the standard recipe.

### Standard Recipe Storage Portion 74 of Recipe Storage Portion 70

The standard recipe stored in the standard recipe storage portion 74 is a processing recipe set in advance for each user at the maker of the laser dicing apparatus 60 according to the type of the workpiece, the required quality, the processing details, or the like. For example, as the standard recipe when the silicon wafer is to be processed, the following processing recipe may be stored in advance in the standard recipe storage portion 74.

### Standard Recipe

Repetitive Frequency: 100 kHz
Processing Feed Speed: 100 mm/s
Spot Diameter: 10 μm
Overlap Rate: 90%

An overlap rate is a rate at which adjacent spots overlap each other, which can be given by Expression 1 shown below:

$$OR = \{ 1 - V / ( d \cdot F ) \} \cdot 100 \qquad Expression 1$$

OR: Overlap Rate (%)
F: Repetitive Frequency (Hz)
V: Processing Feed Speed (mm/s)
d: Spot Diameter (mm)

### Special Recipe Storage Portion 76 of Recipe Storage Portion 70

The special recipe to be stored in the special recipe storage portion 76 is a processing recipe resulting from customization of the details of the standard recipe by the user of the laser dicing apparatus 60. For each of processing conditions in the special recipe, an arbitrary numerical value can be selected from a predetermined numerical value range. For example, in the special recipe for the silicon wafer, for a repetitive frequency of the pulse laser beam and a relative processing feed speed between the chuck table and the spot of the pulse laser beam, arbitrary numerical values can be selected from the following numerical value ranges. However, to prevent the safety factor from being excessively lowered and allow appropriate processing to be performed, the customization is limited. For example, the customization is limited to a range in which the overlap rate is higher than 0% and not more than 90%. Note that an allowable range of the overlap rate is not limited to 0%<Overlap Rate≤90%, and may be set to an arbitrary value according to the type of the workpiece, the required quality, the processing details, or the like.

### Selectable Numerical Value Ranges

Repetitive Frequency: 10 kHz to 300 kHz
Processing Feed Speed: 1 mm/s to 1000 mm/s

### Customization Limiting Portion 72 of Controller 64

When displaying, on the display 66, the standard recipe stored in the standard recipe storage portion 74 and customizing the details of the standard recipe, the customization limiting portion 72 determines whether or not the customization can be allowed on the basis of the correlations between the plurality of items of the standard recipe. In addition, when determining that the customization can be allowed, the customization limiting portion 72 stores the details of the customization as the special recipe in the special recipe storage portion 76 while, when determining that the customization cannot be allowed, the customization limiting portion 72 limits the customization. The customization limiting portion 72 can limit the customization on the basis of the correlations between the repetitive frequency, the processing feed speed, and the spot diameter.

By way of example, it is assumed that the user has attempted the following customization of the foregoing standard recipe for the silicon wafer in which the inappropriate processing may be performed. At this time, the user inputs the repetitive frequency and the processing feed speed from the selectable ranges, while inputting an arbitrary defocus amount. For the spot diameter, a value determined from a width of a laser processed groove formed in the workpiece by preliminarily performing trial processing in the arbitrary defocus amount may also be input or, alternatively, a value calculated from the defocus amount, a thickness of the workpiece, and optical system design values of the laser dicing apparatus 60 may also be input.

### Details of Customization by User

Repetitive Frequency: 100 kHz
Processing Feed Speed: 1000 mm/s
Spot Diameter: 10 μm

Consequently, the overlap rate becomes 0% and inappropriate laser processing may be performed (the laser processing becomes intermittent), and therefore the customization limiting portion 72 determines that the customization cannot be allowed, and limits the customization. Then, the customization limiting portion 72 displays, on the display 66, the allowable one and the unallowable one of the details of the customization input by the user. Alternatively, the customization limiting portion 72 can also display, on the display 66, a limit value to the unallowable one of the details of the customization input by the user.

For example, as in the following customization limit, the customization limiting portion 72 displays, on the display 66, that, for the repetitive frequency, the processing feed speed, and the spot diameter, numerical values input by the user are in allowable ranges, but the overlap rates calculated from respective values of the repetitive frequency, the processing feed speed, and the spot diameter input by the user are not in allowable ranges, and additionally displays a warning message such as “Please change at least any one of the repetitive frequency, the processing feed speed, and the spot diameter such that the overlap rates fall within the allowable ranges”.

### Customization Limit

Repetitive Frequency: 100 kHz Allowable
Processing Feed Speed: 1000 mm/s Allowable
Spot Diameter: 10 μm Allowable
Overlap Rate: 0% Unallowable

Thus, the customization limiting portion 72 displays, on the display 66, the standard recipe stored in the standard recipe storage portion 74 and determines, when customizing the details of the standard recipe, whether or not the customization can be allowed on the basis of the correlations between the plurality of items of the standard recipe, and limits the customization when determining that the customization cannot be allowed. Therefore, it is possible to prevent the safety factor from being excessively lowered when the user customizes the processing recipe and allow appropriate processing to be performed. Note that, as the customization limits, different limits may be set according to the type of the workpiece, the required quality, the processing details, or the like.

### Display 66 of Laser Dicing Apparatus 60

The display 66 displays the processing recipe stored in the recipe storage portion 70 on the basis of an instruction from the controller 64. As described above, the standard recipe stored in the standard recipe storage portion 74 and the special recipe stored in the special recipe storage portion 76 may be displayed on the display 66. In addition, a limit when the standard recipe is to be customized may also be displayed on the display 66. The display 66 may also be a touch panel functioning also as an input interface.

In the creating a special recipe, when the type of the semiconductor wafer 2 is input by the user to each of the controllers 16, 42, and 64, the standard recipe according to the type of the semiconductor wafer 2 is displayed on each of the displays 18, 44, and 66. Then, of the plurality of items included in the standard recipe, an arbitrary item is customized by the user. At this time, for the details of the customization input by the user, it is determined by each of the customization limiting portions 32, 54, and 72 whether or not the customization is such that the safety factor is excessively lowered or whether or not the customization is such that inappropriate processing may be performed (whether or not the customization can be allowed). When the customization is not such that the safety factor is excessively lowered or the inappropriate processing may be performed (when the customization can be allowed), the details of the customization input by the user are stored as the special recipe in each of the special recipe storage portions 36, 58, and 76. In addition, the special recipe stored in each of the special recipe storage portions 36, 58, and 76 is set as a processing recipe for the semiconductor wafer 2.

Meanwhile, when the details of the customization input by the user are the customization in which the safety factor is excessively lowered or the customization in which the inappropriate processing may be performed (when the customization cannot be allowed), a customization limit is displayed on each of the displays 18, 44, and 66 by each of the customization limiting portions 32, 54, and 72. Accordingly, the details of the customization may be input again by the user on the basis of the displayed customization limit. When the details of the customization input again are not the customization in which the safety factor is excessively lowered or the customization in which the inappropriate processing may be performed (when the customization can be allowed), the details of the customization input again are stored as the special recipe in each of the special recipe storage portions 36, 58, and 76. Then, the special recipe stored in each of the special recipe storage portions 36, 58, and 76 is set as the processing recipe for the semiconductor wafer 2.

### Grinding

After creating the special recipe a back surface 2b of the semiconductor wafer 2 is round and thinned according to the special recipe using the processing apparatus 10.

In the grinding and thinning, first, the back surface 2b of the semiconductor wafer 2 is faced upward, and the semiconductor wafer 2 is suction-held on the chuck table 12. Then, the chuck table 12 is rotated in a direction indicated by an arrow R1 in FIG. 2, while the spindle 20 is rotated in a direction indicated by an arrow R2. Then, the spindle 20 is lowered to bring the grinding stones 28 into contact with the back surface 2b of the semiconductor wafer 2, and subsequently the spindle 20 is lowered at a predetermined processing feed speed, while grinding water (e.g., pure water) is supplied. Thus, it is possible to grind the back surface 2b of the semiconductor wafer 2 and thin the semiconductor wafer 2 to a predetermined thickness.

The rotation number of the chuck table 12, the rotation number of the spindle 20, and the processing feed speed (lowering speed) of the spindle 20 in the grinding and thinning have values each based on the special recipe. In the present embodiment, the customization is limited by the customization limiting portion 32 of the grinding apparatus 10 so as to prevent the safety factor from being excessively lowered and allow the appropriate processing to be performed, and therefore it is possible to prevent damage to the grinding apparatus 10, breakage of the semiconductor wafer 2, defective processing, or the like.

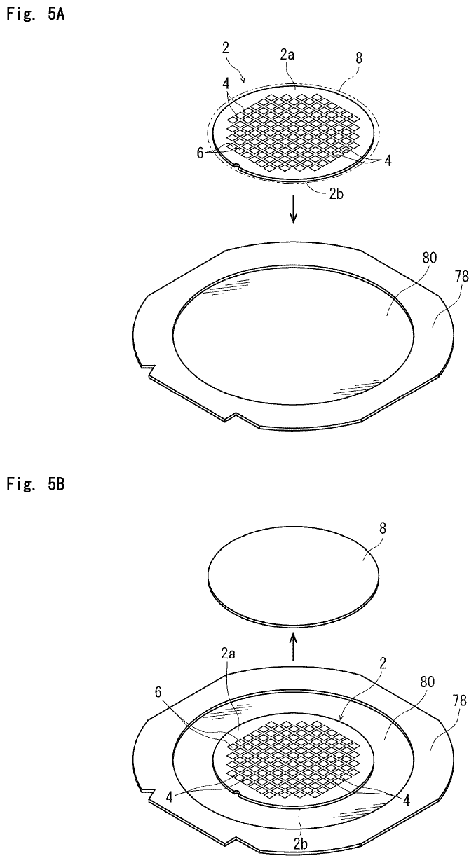

In the present embodiment, after the grinding and thinning, as illustrated in FIG. 5A and FIG. 5B, the back surface 2b of the semiconductor wafer 2 is bonded to a dicing tape 80 supported on an annular frame 78, while the protection member 8 is peeled from the top surface 2a of the semiconductor wafer 2. Thus, the semiconductor wafer 2 is supported on the annular frame 78 via the dicing tape 80. Note that the dicing tape 80 may be either an adhesive tape or a thermo-compression tape.

### Dividing

After the semiconductor wafer 2 is supported on the annular frame 78 via the dicing tape 80, the semiconductor wafer 2 is divided along the division lines 4, so that and form the plurality of semiconductor devices 6 are formed.

### When Blade Dicing Apparatus 38 is Used

The semiconductor wafer 2 can be divided using the blade dicing apparatus 38 illustrated in FIG. 3. When the blade dicing apparatus 38 is used, first, the top surface 2a of the semiconductor wafer 2 is faced upward, and the semiconductor wafer 2 is suction-held on the chuck table (not shown) of the blade dicing apparatus 38. Then, each of the division lines 4 is aligned in an X-axis direction, while the cutting blade 50 is positioned over the division line 4 aligned in the X-axis direction. Then, into the division line 4 aligned in the X-axis direction, the cutting edge of the cutting blade 50 rotated at a high speed is cut from the top surface 2a to the back surface 2b, and the chuck table is processing-fed in the X-axis direction at a predetermined processing feed speed, while cutting water (e.g., pure water) is supplied. Thus, a full-cut groove 82 can be formed along the division line 4 to extend from the top surface 2a to the back surface 2b.

Then, the cutting blade 50 is index-fed in the Y-axis direction by a distance equivalent to an interval between the division lines 4 in the Y-axis direction. Then, by repetitively alternating the formation of the full-cut groove 82 and the index-feeding, the full-cut grooves 82 are formed along all the division lines 4 each aligned in the X-axis direction. Then, after the chuck table is rotated 90 degrees, the formation of the full-cut groove 82 and the index-feeding are repetitively alternated. Thus, the full-cut grooves 82 are formed along all the division lines 4 perpendicular to the division lines 4 along which the full-cut grooves 82 were formed previously. As a result, the semiconductor wafer 2 is diced along the division lines 4, and the plurality of semiconductor devices 6 are formed.

When the semiconductor wafer 2 is divided using the blade dicing apparatus 38, the division method is not limited to that described above, and another method may also be used. For example, the semiconductor wafer 2 may also be diced along the division lines 4 by forming not the full-cut grooves 82 that extend from the top surface 2a to the back surface 2b, but half-cut grooves (not shown) that do not extend from the top surface 2a to the back surface 2b along all the division lines 4 by using the blade dicing apparatus 38, and then applying an external force to the semiconductor wafer 2.

To apply the external force to the semiconductor wafer 2 after the formation of the half-cut grooves, the foregoing grinding apparatus 10 can be used. In other words, by forming the half-cut grooves and then performing the foregoing grinding and thinning, it is possible to expose the half-cut grooves at the back surface 2b of the semiconductor wafer 2 and dice the semiconductor wafer 2 along the division lines 4. Alternatively, a radial external force may also be applied to the semiconductor wafer 2 by forming the half-cut grooves and then stretching the dicing tape 80 radially outwardly by using an expander not shown. Still alternatively, an external force may also be applied to the semiconductor wafer 2 for each of the division lines 4 by forming the half-cut grooves and then pressing a braking bar (not shown) against the back surface 2b side of the semiconductor wafer 2 along the division line 4.

When the blade dicing apparatus 38 is used to divide the semiconductor wafer 2, each of the rotation number of the spindle 48 and the processing feed speed of the chuck table has a value based on the special recipe. In the present embodiment, the customization limit is placed by the customization limiting portion 54 of the blade dicing apparatus 38 so as to prevent the safety factor from being excessively lowered and allow the appropriate processing to be performed, and therefore it is possible to prevent damage to the blade dicing apparatus 38, breakage of the semiconductor wafer 2, defective processing, or the like.

### When Laser Dicing Apparatus 60 is Used

The semiconductor wafer 2 can also be divided using the laser dicing apparatus 60 illustrated in FIG. 4. When the laser dicing apparatus 60 is used, first, the top surface 2a of the semiconductor wafer 2 is faced upward, and the semiconductor wafer 2 is suction-held on the chuck table of the laser dicing apparatus 60. Then, each of the division lines 4 is aligned in the X-axis direction, and then the laser beam LB is aimed at the division line 4 aligned in the X-axis direction, while a focal spot of the laser beam LB is positioned on the upper surface of the semiconductor wafer 2. Then, the laser beam LB with a wavelength absorbable by the semiconductor wafer 2 is applied to the semiconductor wafer 2, while the chuck table is processing fed at a predetermined processing feed speed in the X-axis direction. Thus, it is possible to perform ablation processing along the division line 4 and form the full-cut groove 82 extending from the top surface 2a to the back surface 2b. Then, the application of the laser beam LB and the index-feeding are repetitively alternated to form the full-cut grooves 82 along all the division lines 4 in the same manner as when the blade dicing apparatus 38 is used. As a result, the semiconductor wafer 2 is diced along the division lines 4, and the plurality of semiconductor devices 6 are formed.

When the semiconductor wafer 2 is divided using the laser dicing apparatus 60, the division method is not limited to that described above, and another method may also be used. For example, the semiconductor wafer 2 may also be diced along the division lines 4 by forming not the full-cut grooves 82 that extend from the top surface 2a to the back surface 2b, but the half-cut grooves (not shown) that do not extend from the top surface 2a to the back surface 2b along all the division lines 4 by using the laser dicing apparatus 60 and then applying an external force to the semiconductor wafer 2. The half-cut grooves can be formed by ablation processing.

Alternatively, the semiconductor wafer 2 can also be diced along the division lines 4 by using the laser dicing apparatus 60 to form the modifying layers inside of the semiconductor wafer 2 along all the division lines 4 and then applying an external force to the semiconductor wafer 2. To form the modifying layers, it may be appropriate to position a focal spot of a laser beam with a wavelength transparent to the semiconductor wafer 2 inside of the semiconductor wafer 2 and apply the laser beam to the semiconductor wafer 2.

The external force to be applied to the semiconductor wafer 2 after the formation of the half-cut grooves or the modifying layers can be applied using the grinding apparatus 10, the expander, the braking bar, or the like. Note that, when the grinding apparatus 10 is to be used, unlike in the present embodiment, the half-cut-grooves or the modifying layers are formed, and then the foregoing grinding and thinning is performed.

When the laser dicing apparatus 60 is used to divide the semiconductor wafer 2, each of the repetitive frequency, the processing feed speed, the spot diameter, and the overlap rate has a value based on the special recipe. In the present embodiment, the customization has been limited by the customization limiting portion 72 of the laser dicing apparatus 60 so as to prevent the safety factor from being excessively lowered and allow the appropriate processing to be performed, and therefore it is possible to prevent damage to the laser dicing apparatus 60, the breakage of the semiconductor wafer 2, the defective processing, or the like.

Note that, when the semiconductor wafer 2 is subjected to ablation processing, the top surface 2a of the semiconductor wafer 2 may appropriately be covered with a protection film (not shown) made of a water-soluble resin or the like in advance such that debris produced during the ablation processing does not adhere to the top surface 2a of the semiconductor wafer 2.

In the dividing, it may also be possible to form the full-cut grooves 82 by using a plasma etching apparatus and dice the semiconductor wafer 2 along the division lines 4, though not shown. Alternatively, it may also be possible to form the half-cut grooves by using the plasma etching apparatus and then dice the semiconductor wafer 2 along the division lines 4 by applying an external force to the semiconductor wafer 2.

In the embodiment described above, the semiconductor wafer 2 is supported on the annular frame 78 via the dicing tape 80, but it may also be possible to perform the dividing in a state where the protection member 8 is attached to the top surface 2a of the semiconductor wafer 2 without supporting the semiconductor wafer 2 with the annular frame 78. Also, in the embodiment described above, the creating a special recipe, the grinding, and the dividing are performed in this order, but it may also be possible to omit the grinding and perform the dividing after the creating a special recipe.

### REFERENCE SIGNS LIST

2 Semiconductor wafer
2a Top surface of semiconductor wafer
2b Back surface of semiconductor wafer
4 Division line
6 Semiconductor device
10 Grinding apparatus (processing apparatus)
16 Controller
18 Display
38 Blade dicing apparatus (processing apparatus)
42 Controller
44 Display
60 Laser dicing apparatus (processing apparatus)
64 Controller
66 Display

What is claimed is:

1. A workpiece processing method comprising:
creating a special recipe by customizing a standard recipe in a processing apparatus in which the standard recipe is stored; and
processing the workpiece according to the special recipe using the processing apparatus.

2. The workpiece processing method of claim 1, wherein, in the creating the special recipe, a controller of the processing apparatus determines whether or not the customization can be allowed on the basis of a correlation between a plurality of items of the standard recipe and, when determining that the customization can be allowed, the controller stores details of the customization as the special recipe and, when determining that the customization cannot be allowed, the controller limits the customization.

3. The workpiece processing method of claim 1, wherein, in the creating the special recipe, when determining that the customization cannot be allowed, the controller displays, on a display of the processing apparatus, an allowable one and an unallowable one of details of the customization.

4. The workpiece processing method of claim 1, wherein, in the creating the special recipe, when determining that the customization cannot be allowed, the controller displays, on a display of the processing apparatus, a limit value to an unallowable one of details of the customization.

5. A semiconductor device manufacturing method comprising:
preparing a semiconductor wafer having a semiconductor device in each of surface regions thereof defined by a plurality of division lines crossing each other;
creating a special recipe by customizing a standard recipe in a processing apparatus in which the standard recipe is stored;
grinding and thinning a back surface of the semiconductor wafer according to the special recipe using the processing apparatus; and
dividing the semiconductor wafer along the division lines to form a plurality of the semiconductor devices.

6. A semiconductor device manufacturing method comprising:
preparing a semiconductor wafer having a semiconductor device in each of surface regions thereof defined by a plurality of division lines crossing each other;
creating a special recipe by customizing a standard recipe in a processing apparatus in which the standard recipe is stored; and
dividing the semiconductor wafer along the division lines to form a plurality of the semiconductor devices,
the dividing including dicing the semiconductor wafer using the processing apparatus along the division lines of the semiconductor wafer according to the special recipe.

7. The semiconductor device manufacturing method of claim 5, wherein, in the creating the special recipe, a controller of the processing apparatus determines whether or not the customization can be allowed on the basis of a correlation between a plurality of items of the standard recipe and, when determining that the customization can be allowed, the controller stores details of the customization as the special recipe and, when determining that the customization cannot be allowed, the controller limits the customization.

8. The semiconductor device manufacturing method of claim 6, wherein, in the creating the special recipe, a controller of the processing apparatus determines whether or not the customization can be allowed on the basis of a correlation between a plurality of items of the standard recipe and, when determining that the customization can be allowed, the controller stores details of the customization as the special recipe and, when determining that the customization cannot be allowed, the controller limits the customization.

9. The semiconductor device manufacturing method of claim 5, wherein, in the creating the special recipe, when determining that the customization cannot be allowed, the controller displays, on a display of the processing apparatus, an allowable one and an unallowable one of details of the customization.

10. The semiconductor device manufacturing method of claim 6, wherein, in the creating the special recipe, when determining that the customization cannot be allowed, the controller displays, on a display of the processing apparatus, an allowable one and an unallowable one of details of the customization.

11. The semiconductor device manufacturing method of claim 5, wherein, in the creating the special recipe, when determining that the customization cannot be allowed, the controller displays, on a display of the processing apparatus, a limit value to an unallowable one of details of the customization.

12. The semiconductor device manufacturing method of claim 6, wherein, in the creating the special recipe, when determining that the customization cannot be allowed, the controller displays, on a display of the processing apparatus, a limit value to an unallowable one of details of the customization.
